(19) United States
(12) Patent Application Publication
(10) Pub. No.: US 2009/0056627 A1
(43) Pub. Date: Mar. 5, 2009

(54) METHOD AND APPARATUS FOR MONITORING PLASMA-INDUCED DAMAGE USING DC FLOATING POTENTIAL OF SUBSTRATE

(75) Inventors: Mitsutoshi SHUTO, Tokyo (JP); Yasushi FUKASAWA, Tokyo (JP); Yasuaki SUZUKI, Tokyo (JP)

Correspondence Address: KNOBBE MARTENS OLSON & BEAR LLP, 2040 MAIN STREET, FOURTEENTH FLOOR, IRVINE, CA, 92614, US

(73) Assignee: ASM JAPAN K.K., Tokyo (JP)

(21) Appl. No.: 11/847,962

(22) Filed: Aug. 30, 2007

(51) Int. Cl. B05C 11/00; G01N 27/66; G01R 29/12

(52) U.S. Cl. 118/712; 324/457; 324/71.1

(57) ABSTRACT

A method for monitoring plasma-induced damage to a substrate while being processed in a plasma CVD apparatus includes: measuring DC floating potential of the substrate using a detection electrode in contact with the substrate while the substrate is processed in the apparatus; and detecting abnormality as plasma-induced damage based on the measured DC floating potential.

### BACKGROUND OF THE INVENTION

1. Field of the Invention

The present invention relates to a method for monitoring plasma-induced damage caused by increased charges, etc., on a plasma processing apparatus (especially a sheet-feed plasma CVD apparatus) used in a semiconductor manufacturing process.

2. Description of the Related Art

Although dry etching, plasma CVD and other plasma processings are widely used in the production of semiconductor apparatuses, these plasma processing apparatuses present a major problem of damage induced by plasma.

The floating potential of the semiconductor substrate generated by electrons during plasma processing triggers charging damage and adsorption problem. Since occurrence of such damage often results in an abnormal DC bias voltage Vdc at the electrodes, Vdc has been traditionally used in the monitoring of plasma-induced damage.

Plasma processing apparatuses incorporate a circuit for measuring the AC voltage Vpp and DC bias voltage Vdc, in a RF matching device provided along the path through which radio frequencies are supplied from the RF power supply to the upper electrode, and the Vdc signal detected by this measurement circuit is used to check plasma stability and detect abnormality.

In addition to the above, a number of methods are known where the AC voltage and DC voltage of various parts are measured and used. Some examples are cited below.

For example, Japanese Patent Laid-open No. 2005-142582 describes a method that uses AC measurement of the semiconductor substrate. Here, the impedance is calculated from the AC voltage and AC current of the semiconductor substrate and stage, to be used in the control of etching parameters. The AC potential of the semiconductor substrate is also monitored to detect plasma abnormality.

Japanese Patent Laid-open No. 2002-270577 discloses a method whereby the DC voltage around the top plate is measured during plasma processing for use in the control of plasma.

Japanese Patent Laid-open No. 2005-310945 discloses a method whereby the DC voltage of the semiconductor substrate is measured after completion of plasma processing for use in the judgment of adsorption.

Japanese Patent Laid-open No. Hei 07-13518 discloses a method whereby the DC voltage of the lower electrode is measured using the split resistance and the measurements are used for the control of ion energy.

### SUMMARY OF THE INVENTION

Among the aforementioned methods, those that measure DC voltage do so for the purpose of plasma control and not to monitor damage. Also, none of them measure the substrate directly.

In addition, the abnormal detection based on the AC voltage of the substrate as described in Japanese Patent Laid-open No. 2005-142582 is unable to detect abnormality in situations where the DC voltage is abnormal but the AC voltage does not show any abnormality.

At any rate, none of these methods directly measure and monitor the DC voltage of the substrate for the purpose of monitoring damage during plasma processing.

If the substrate sustains damage during plasma processing, the voltage applied to the substrate changes. In addition to this voltage change, the DC bias voltage applied to the entire lower electrode, and even the DC voltage applied to the upper electrode, also change. For this reason, monitoring the Vdc level of the upper electrode has been considered an effective way to detect damage.

However, an occurrence of substrate abnormality is not always accompanied by a change in the DC bias voltage of the upper electrode or lower electrode, and there are many cases where substrate abnormality occurs without the DC bias voltage of the upper electrode or lower electrode showing any abnormality.

The reverse is also true, meaning that the substrate may be perfectly normal even when the DC voltage of the upper electrode or lower electrode is abnormal.

There are also cases where the AC voltage is normal even when the DC bias voltage is abnormal.

Plasma damage is caused by substrate abnormality occurring during plasma processing and may not be detected by simply monitoring the electrodes and AC voltage. For this reason, the DC bias voltage of the substrate itself must be measured directly to monitor plasma damage.

In view of the above, in an embodiment of the present invention an apparatus having a grounded lower electrode is used and the DC bias voltage of the substrate is measured directly during plasma processing using a measurement circuit with a sufficiently large input resistance, in order to monitor plasma damage.

By directly measuring the DC bias voltage of the substrate during plasma processing, substrate damage can be detected more accurately than heretofore possible.

Also by using a measurement circuit with a sufficiently large input resistance, the effect of the film formed on the reverse side of the substrate can be virtually ignored.

For purposes of summarizing the invention and the advantages achieved over the related art, certain objects and advantages of the invention are described in this disclosure. Of course, it is to be understood that not necessarily all such objects or advantages may be achieved in accordance with any particular embodiment of the invention. Thus, for example, those skilled in the art will recognize that the invention may be embodied or carried out in a manner that achieves or optimizes one advantage or group of advantages as taught herein without necessarily achieving other objects or advantages as may be taught or suggested herein.

Further aspects, features and advantages of this invention will become apparent from the detailed description of the preferred embodiments which follow.

### BRIEF DESCRIPTION OF THE DRAWINGS

These and other features of this invention will now be described with reference to the drawings of preferred embodiments which are intended to illustrate and not to limit the invention. The drawings are oversimplified for illustrative purposes and are not to scale.

FIG. 1 is a schematic diagram of a plasma CVD apparatus according to an embodiment of the present invention.

FIGS. 2(a) to 2(d) are graphs showing changes of Vpp (DC voltage), Vdc (DC bias voltage), and Vf (wafer floating potential) while processing a wafer in a plasma CVD apparatus according to an embodiment of the present invention. FIG. 2(a) shows a normal state, and FIGS. 2(b) to 2(d) show abnormal states.

FIGS. 3(a) and 3(b) are schematic diagrams of a top plate provided with a detection electrode according to an embodiment of the present invention. FIG. 3(a) shows an assembled state, and FIG. 3(b) shows a disassembled state.

FIGS. 4(a) and 4(b) are schematic diagrams of a top plate provided with a detection electrode according to another embodiment of the present invention. FIG. 4(a) shows an assembled state, and FIG. 4(b) shows a disassembled state.

FIG. 5 is a schematic diagram of a top plate provided with a detection electrode according to still another embodiment of the present invention.

### DETAILED DESCRIPTION OF THE PREFERRED EMBODIMENT

The present invention will be explained with respect to preferred embodiments. However, the preferred embodiments are not intended to limit the present invention.

In an embodiment, a method for monitoring plasma-induced damage to a substrate while being processed in a plasma CVD apparatus, comprises: (i) measuring DC floating potential of the substrate using a detection electrode in contact with the substrate while the substrate is processed in the apparatus; and (ii) detecting abnormality as plasma-induced damage based on the measured DC floating potential of the substrate. By the above method, DC bias voltage can be measured directly from the substrate, which is more accurately indicative of abnormality of the plasma processing (e.g., plasma-induced charge-up damage to the substrate).

The above embodiment includes, but is not limited to, the following embodiments:

The method may further comprise stopping the processing of the substrate when the abnormality is detected. This can be accomplished automatically or manually. In an embodiment, when the abnormality is detected, an alarm signal may go off.

In any one of the foregoing embodiments, in the step of measuring DC floating potential, the detection electrode may be in contact with an underside of the substrate.

In any one of the foregoing embodiments, the detection electrode may be connected to a voltmeter having an input resistance (the resistance of the detection circuit) of 100 MΩ or higher, and the DC floating potential of the substrate may be measured by the voltmeter. When the input resistance of the voltmeter is high, effect of a film present on a underside of the substrate on the measurement can be rendered negligible. Alternatively, in any one of the foregoing embodiments, the detection electrode may be connected to an electrostatic field strength measuring device, and the electrostatic field strength may be measured as the DC floating potential of the substrate. By measuring the electrostatic field strength of the substrate, the DC floating potential of the substrate can also be detected. In this case, effect of a film present on a underside of the substrate on the measurement can also be rendered negligible.

In any one of the foregoing embodiments, the substrate may be placed on a susceptor, and a top surface of the detection electrode may be leveled with a top surface of the susceptor, wherein the detection electrode is insulated from the susceptor. Alternatively, in any one of the foregoing embodiments, the substrate may be placed on a susceptor having trough-holes in which lift pins for lifting the substrate are inserted, said lift pins being movable with respect to the susceptor in an axial direction of the susceptor and insulated from the susceptor, wherein one of the lift pins serves as the detection electrode. In the above embodiments, measuring the floating potential of the substrate can be performed accurately and reliably without complicated or expensive equipment.

In another embodiment, the present invention provides an plasma CVD apparatus for processing a substrate, comprising: (a) a reaction chamber; (b) a shower plate disposed in the reaction chamber and functioning as an upper electrode for plasma generation; (c) a susceptor disposed in the reaction in parallel to the shower plate and functioning as a lower electrode for plasma generation; and (d) an electrode for measuring DC floating potential of a substrate placed on the susceptor, said electrode being insulated from the susceptor and configured to be in contact with the susceptor while the substrate is processed in the reaction chamber.

The above embodiment includes, but is not limited to, the following embodiments:

In an embodiment, the apparatus may further comprise a voltmeter disposed outside the reaction chamber for measuring the DC floating potential, said voltmeter being connected to the detection electrode and having an input resistance of 100 MΩ or higher. In another embodiment, the apparatus may further comprise an electrostatic field strength measuring device disposed outside the reaction chamber for measuring the electrostatic field strength of the substrate as the DC floating potential, said electrostatic field strength measuring device being connected to the detection electrode.

In any one of the foregoing embodiments, a top surface of the detection electrode may be exposed from a top surface of the susceptor to be in contact with an underside of the substrate.

In the above, the top surface of the detection electrode may be leveled with the top surface of the susceptor, wherein the detection electrode is insulated from the susceptor. In an embodiment, the susceptor may be composed of a top plate and a heating block on which the top plate is placed, wherein both the detection electrode and its connecting wire leading to an outside of the reaction chamber are detachably embedded in the top plate via an insulating material and do not extend through the heating block. In another embodiment, the susceptor may be composed of a top plate and a heating block on which the top plate is placed, wherein the detection electrode is detachably embedded in the top plate via an insulating material, and a connecting wire connecting the detection electrode and an outside of the reaction chamber extends through the heating block via an insulating material. In still another embodiment, the susceptor may include a heater, wherein the detection electrode and its connecting wire leading to an outside of the reaction chamber are detachably embedded in the susceptor via an insulating material.

Alternatively, in an embodiment, the susceptor may have trough-holes in which lift pins for lifting the substrate are inserted, said lift pins being movable with respect to the susceptor in an axial direction of the susceptor and insulated from the susceptor, wherein one of the lift pins serves as the detection electrode.

In any one of the foregoing embodiments, the susceptor may be grounded. Alternatively, instead of the upper electrode, the susceptor (the lower electrode) can be connected to an RF power source, or both the upper and lower electrodes can be connected to RF power sources, respectively.

Next, the present invention will be explained with reference to drawings and examples. However, the drawings and examples are not intended to limit the present invention. In the present disclosure where conditions and/or structures are not specified, the skilled artisan in the art can readily provide such conditions and/or structures, in view of the present disclosure, as a matter of routine experimentation.

Also, in the present disclosure, the numerical numbers applied in embodiments can be modified by ±50% in other embodiments, and the ranges applied in embodiments may include or exclude the endpoints.

### Configuration of Apparatus

### [Overall]

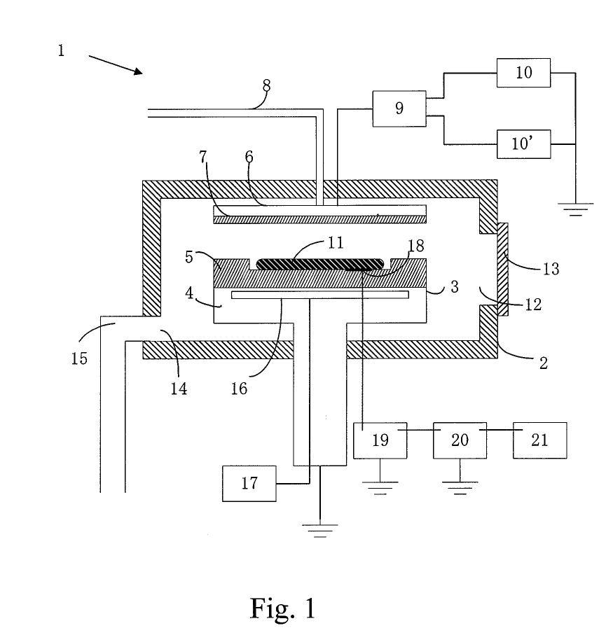

The plasma CVD apparatus for forming a film on a semiconductor substrate, as shown in FIG. 1, comprises a reaction chamber 2, a susceptor 3 for placing a semiconductor substrate on top, a shower head 6, 7 installed in a manner facing the susceptor and used to inject reactant gas uniformly onto the semiconductor substrate, a gas introduction pipe 8 for introducing gas to the reaction chamber, an exhaust port 14 for evacuating the interior of the reaction chamber, an opening 12 for loading/unloading a semiconductor substrate into/out of the reaction chamber, two types of RF power supplies 10, 10′ for applying specified voltages, and a matching device 9 for rectifying the two types of radio frequencies and maintaining the impedance at a specified level.

### [Opening]

The opening 12 is provided in the side face of the reaction chamber 2, while the reaction chamber is connected to a load chamber (not illustrated) for loading and unloading a semiconductor substrate via a gate valve 13.

### [Exhaust Port]

The exhaust port 14 is provided in the reaction chamber, and the exhaust port is connected to a vacuum evacuation pump (not illustrated) via a pipe line 15. Provided between the exhaust port 14 and the vacuum pump is a mechanism (not illustrated) for detecting the internal pressure of the reaction chamber and another mechanism (not illustrated) for adjusting the pressure, so that the internal pressure of the reaction chamber can be controlled at a specified level.

### [Upper Electrode]

In the reaction chamber 2, a shower head 6, 7 is installed in a position facing the susceptor 3. The reactant gas introduction pipe 8 for introducing reactant gas is connected to the shower head, and reactant gas is injected into the reaction chamber through the several thousand small holes (not illustrated) provided in the bottom face 7 of the shower head for ejecting reactant gas onto a substrate 11. The shower head is also electrically connected to RF power supplies via a RF matching device 9, and constitutes one electrode used in plasma discharge.

### [Lower Electrode]

In the reaction chamber 2, the susceptor 3 on which to place a semiconductor substrate 11 comprises a top plate 5 having a placement surface coated with an anodic oxidation film and used to place a semiconductor substrate on top, and a heater 4 having an embedded heating element 16 and used to heat the semiconductor substrate. The heater 4 is grounded and the susceptor constitutes the other electrode used in plasma discharge.

The top plate 5 is detachably/attachably affixed to the heater 4 with screws, etc. However, connecting the top plate 5 and heater 4 in a non-detachable/attachable manner will not present any problem at all.

The heater 4 is connected to a drive mechanism (not illustrated) for moving the susceptor up and down outside the reactor.

The heating element 16 of resistance-heating type is embedded in the heater 4, and connected to an external power supply and a temperature controller 17. The heating element is controlled in such a way that the susceptor is heated to a desired temperature (300° C. to 650° C.) by means of the temperature controller.

### EXAMPLE 1

### (Overall Configuration)

Numeral 18 in FIG. 1 indicates a measurement electrode that contacts the substrate 11 and measures the substrate voltage. The signal from the measurement electrode is connected to a static field strength meter 20 outside the reactor 2 via a RF removal filter 19, and the static strength meter 20 measures the DC bias voltage of the substrate 11. Any RF removal filter can be used as long as it can remove radio frequencies. Normally, this filter can be constituted by combining a coil, resistor and capacitor. The static field strength meter, which is also called a surface potential meter, may be any device as long as it can measure the surface potential (or charge potential) of a charged object based on the static field strength of the object. For your information, although the static field strength of the measuring target is measured without contacting the target, in this figure the potential of the substrate is sent to the static field strength meter through the filter via the measurement electrode contacting the substrate, and the static field strength is measured in a non-contact manner inside the static field strength meter.

The output signal from the static field strength meter is output to a controller 21 that controls the entire apparatus.

The controller 21 monitors the DC voltage of the substrate and when the voltage exceeds the specified value or deviates from the specified fluctuation band, it will determine that an abnormality has occurred and implement the specified interruption processing.

The controller also monitors the DC voltage after plasma processing and implements a control whereby the susceptor will not be driven unless the voltage drops to the specified level or below, in order to solve the adsorption problem.

### EXAMPLE 2

### (Tunnel Top Plate)

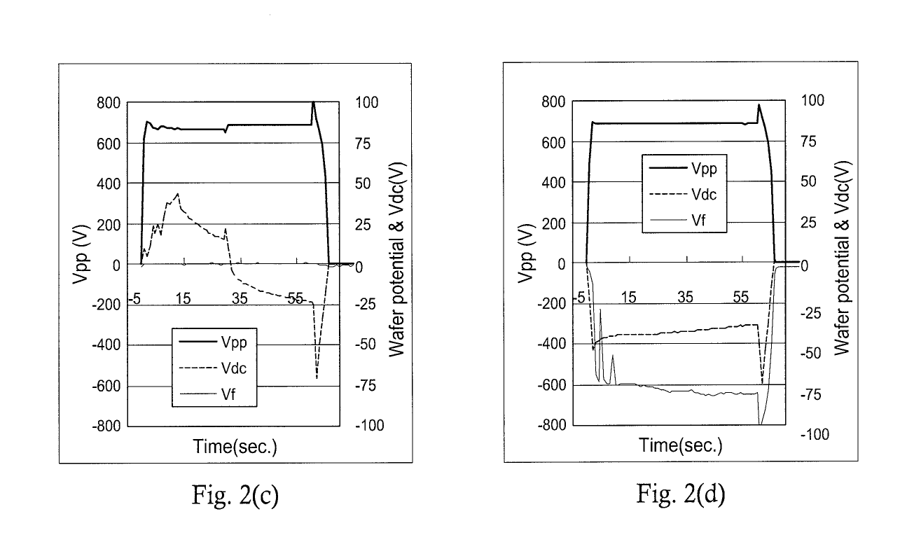

An example of a susceptor used to measure the substrate voltage is shown in FIGS. 3(a) and 3(b). A top plate 31 is detachably/attachably affixed to the susceptor with screws, etc. The top plate 31 is made of aluminum, aluminum alloy, etc., and its top and side faces are treated by anodic oxidation.

The top plate 31 has a hole 39 with a diameter of approx. 1 cm, and a single groove 38 connecting this hole to the periphery is provided on the reverse side. A measurement electrode 37 for measuring the substrate voltage and an electrode cover 34 made of an insulating material are inserted into this hole 39. The measurement electrode is typically made of aluminum, but nickel, tungsten, stainless steel or any other conductive material can be used without specific limitations. The insulating material is normally ceramic or quartz but is not limited thereto and it may be made of at least one material constituted by an oxide, nitride, or fluoride of aluminum, magnesium, silicon, titanium, or zirconium.

The electrode cover 34 is structured in such a way that it covers the side and bottom faces of the measurement electrode 37 to prevent the measurement electrode 37 from contacting the top plate 31 or heater. A hole 35 for guiding a conductive wire is provided in the side face of the cover. The measurement electrode 37 is inserted into this electrode cover 34, and once the electrode has been installed the surface of the top plate 31 becomes the same height as the surface of the measurement electrode, with the measurement electrode contacting the substrate.

The conductive wire 33 is laid in the groove 38 at the bottom of the top plate 31. This conductive wire 33 is covered with an insulating material 32 to be electrically insulated from the top plate 31, heater, and plasma. Ceramic, quartz or Teflon is normally used as this insulating material, but the material is not limited thereto and may be made of at least one material constituted by an oxide, nitride, or fluoride of aluminum, magnesium, silicon, titanium, or zirconium (or the like can be used). One end of this conductive wire is connected to the measurement electrode 37 through the hole 35 provided in the side face of the electrode cover 34, while the other end is connected via the RF filter to the static field strength meter outside the reactor through the hole 38 provided at the bottom of the top plate 31.

The aforementioned measurement electrode 37, electrode cover 34 and conductive wire 33 are all detachable/attachable, as shown in FIG. 3(b), for easy replacement. With the apparatus conforming to this example, the only component requiring change is the top plate 31 and the heater and other components may remain the same as the components used in conventional apparatuses.

For your information, although the measurement electrode 37 has a T-shaped longitudinal cross-section in this example, other electrode shapes may also be used. Also, the measurement electrode 37 is provided between the center and outer periphery of the substrate when the substrate is placed on the top plate, and its position roughly corresponds to the midpoint in this example. However, the position is not limited to the above and any position may be selected as deemed appropriate as long as the electrode can contact the reverse side of the substrate. If the top plate has a gradual concaved surface, for example, the measurement electrode is positioned in a manner directly contacting the substrate near its outer periphery. Also in this example, the diameter of the direct contact surface of the measurement electrode is approx. 1 cm. However, any diameter can be selected as deemed appropriate in a range of approx. 0.3 cm to 2 cm. Also, it is desirable that the area of the electrode cover 34 exposed from below the top plate surface be made as small as possible while ensuring sufficient insulation property of the electrode. For example, the thickness of the electrode cover between the measurement electrode and top plate is between approx. 0.2 mm and 2 mm. Also, multiple measurement electrodes may be provided instead of limiting the number of measurement electrode to only one. Although the top plate has a lip in this example, the plate need not have a lip.

### EXAMPLE 3

### (Top Plate, Heater-Through Type)

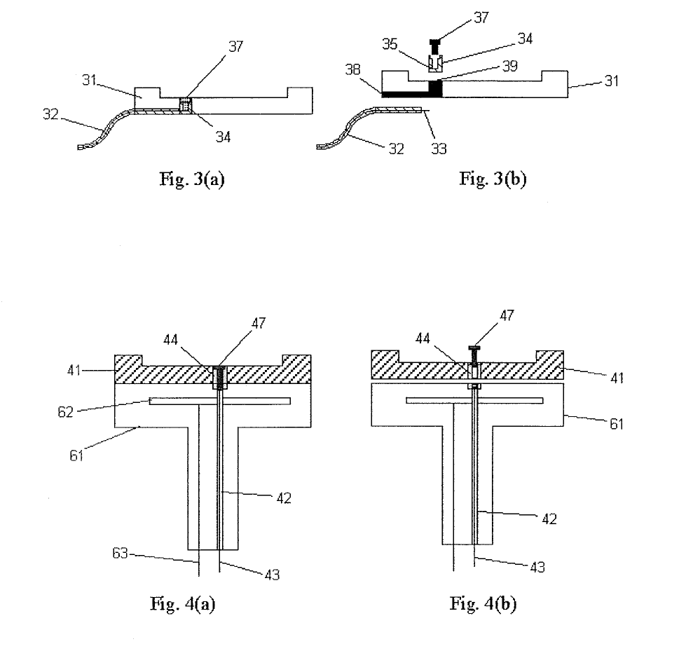

Another example of a susceptor for measuring the substrate voltage is shown in FIGS. 4(a) and 4(b). Although the susceptor shown in this example is a separate type, either an integrated or separate susceptor may be used. A measurement electrode 47 pierces through a top plate 41 and connects to a conductive wire 43 via a heater 61. The measurement electrode 47 is encased in an insulation cylinder 44 to prevent the top plate 41 and heater 61 from contacting the electrode. The conductive wire 43 is covered with an insulating material 42 and guided to outside the reactor from the bottom of the heater along with other wires (such as a wire 63 connected to a heating element 62). The material of each part and other elements of configuration can be implemented according to Example 2. Here, the measurement electrode is positioned at the corresponding top plate surface (near the substrate center) in the axial direction as viewed from the bottom face of the heater, for the sheer convenience of guiding the conductive wire to outside the reactor. However, the position of the measurement electrode is not limited to the above and the electrode may also be provided near the outer periphery of the heater.

### EXAMPLE 4

### (Support Pin Type)

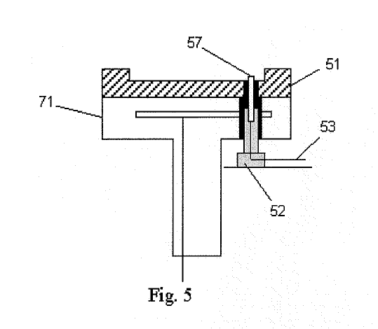

FIG. 5 shows another example of substrate voltage measurement. A support pin is used to support the semiconductor substrate as it is transferred. Here, this support pin is made of a conductive material and used as the measurement electrode. A base 52 that supports a support pin 57 is partially or entirely made of an insulating material so that the pin 57 encased in a cavity 56 is insulated from a heater 71 and reactor. The pin is connected to a conductive wire 53 at the bottom, and the conductive wire 53 is guided to outside the reactor from the bottom of the base 52. The support pin 57 reaches the same height as a top plate 51 once the heater 71 has been raised to the plasma processing height. In this example, neither the heater 71 nor top plate 51 has a dedicated hole or other structure for measurement electrode and thus no modification is required. For this reason, this configuration provides an effective method when, for example, detecting damage of a specific top plate.

As explained above, in an embodiment of the present invention the DC bias voltage of the substrate is measured directly to detect substrate damage more accurately than heretofore possible. Furthermore, in an embodiment the effect of the film formed on the reverse side of the substrate can be virtually ignored by using a static field strength meter. In an embodiment, occurrence of adsorption problem can be prevented by measuring the voltage of the substrate after completion of plasma processing.

### EXPERIMENTAL EXAMPLE

As a comparative example, the apparatus without measurement electrode as shown in FIG. 1 was used to actually process a substrate and the circuit (not illustrated) incorporated in the RF matching device was used to measure the applicable RF AC voltage (Vpp) and DC bias voltage (Vdc). As an example, the apparatus shown in FIGS. 1 and 3(a) and 3(b) was used to measure the DC voltage (Vf) of the substrate in the same manner. The film forming conditions used are as follows: TEOS=86 sccm, O2=800 sccm, Pressure=3.0 Torr, Susceptor temperature=400° C., RF (13.56 MHz)=285 W, and RF (250 kHz)=250 W.

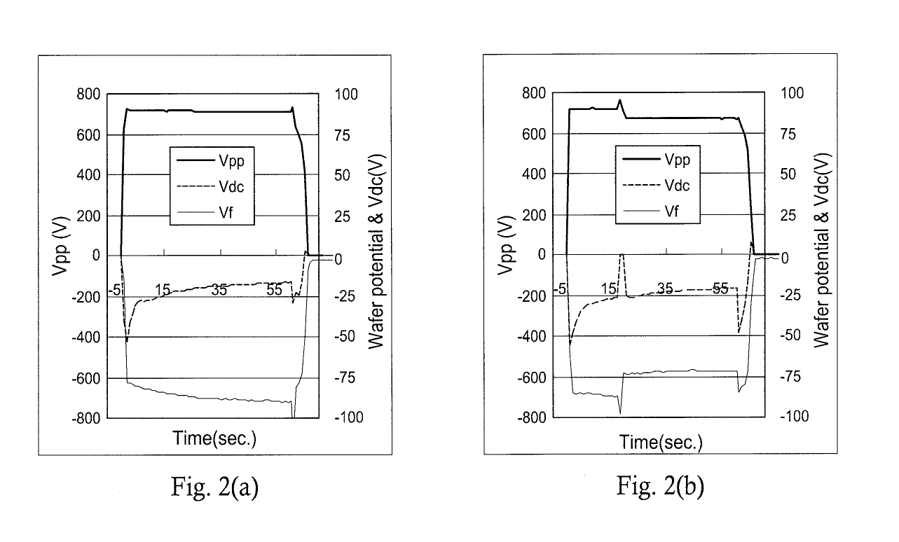

The results are shown in FIGS. 2(a) through 2(d). These graphs illustrate data taken from one minute of TEOS film formation. In the four graphs, Vf indicates the substrate voltage. The graph in FIG. 2(a) represents a normal condition. The graph in FIG. 2(b) shows abnormality occurring at a point of around 20 seconds. As you can see, both the values of Vdc and Vf undergo change at this point. The graph in FIG. 2(c) also shows an abnormal condition. Here, the substrate voltage becomes 0 V, indicating that the substrate and top plate have shorted. Abnormality is not readily noticeable in Vpp or Vdc. Although no clear abnormality is detected in Vpp or Vdc in the graph in FIG. 2(d), abnormal Vf is detected. Here, no abnormality is detected in Vpp or Vdc, and this may be because although current flowed from the substrate to the ground due to, for example, a drop in resistance caused by abnormality occurring in a part of the anodic oxidation film on the top plate, the change in resistance was small, the current flowed only for a short period of time, or for other reason. However, it is understood that abnormality can be detected in Vf.

As for “abnormal” values, it is impossible to generalize the specific levels of normal and abnormal values because the DC voltage varies depending on the apparatus configuration and process conditions. However, those skilled in the art should be able to easily set appropriate values in individual cases. If necessary, damage can be evaluated from the DC voltage of the substrate measured during processing and also from the surface potential or other data of the substrate measured after formation of film, and a correlation may be obtained to set “abnormal” values.

It will be understood by those of skill in the art that numerous and various modifications can be made without departing from the spirit of the present invention. Therefore, it should be clearly understood that the forms of the present invention are illustrative only and are not intended to limit the scope of the present invention.

1. A method for monitoring plasma-induced damage to a substrate while being processed in a plasma CVD apparatus, comprising:
measuring DC floating potential of the substrate using a detection electrode in contact with the substrate while the substrate is processed in the apparatus; and
detecting abnormality as plasma-induced damage based on the measured DC floating potential of the substrate.

2. The method according to claim 1, further comprising stopping the processing of the substrate when the abnormality is detected.

3. The method according to claim 1, wherein the detection electrode is connected to a voltmeter having an input resistance of 100 MΩ or higher, and the DC floating potential of the substrate is measured by the voltmeter.

4. The method according to claim 1, wherein the detection electrode is connected to an electrostatic field strength measuring device, and the electrostatic field strength is measured as the DC floating potential of the substrate.

5. The method according to claim 1, wherein in the step of measuring DC floating potential, the detection electrode is in contact with an underside of the substrate.

6. The method according to claim 5, wherein the substrate is placed on a susceptor, and a top surface of the detection electrode is leveled with a top surface of the susceptor, wherein the detection electrode is insulated from the susceptor.

7. The method according to claim 5, wherein the substrate is placed on a susceptor having trough-holes in which lift pins for lifting the substrate are inserted, said susceptor being movable in an axial direction of the susceptor with respect to the lift pins and insulated from the lift pins, wherein one of the lift pins serves as the detection electrode.

8. An plasma CVD apparatus for processing a substrate, comprising:
a reaction chamber;
a shower plate disposed in the reaction chamber and functioning as an upper electrode for plasma generation;
a susceptor disposed in the reaction in parallel to the shower plate and functioning as a lower electrode for plasma generation; and
an electrode for measuring DC floating potential of a substrate placed on the susceptor, said electrode being insulated from the susceptor and configured to be in contact with the susceptor while the substrate is processed in the reaction chamber.

9. The apparatus according to claim 8, further comprising a voltmeter disposed outside the reaction chamber for measuring the DC floating potential, said voltmeter being connected to the detection electrode and having an input resistance of 100 MΩ or higher.

10. The apparatus according to claim 8, further comprising an electrostatic field strength measuring device disposed outside the reaction chamber for measuring the electrostatic field strength of the substrate as the DC floating potential, said electrostatic field strength measuring device being connected to the detection electrode.

11. The apparatus according to claim 8, wherein a top surface of the detection electrode is exposed from a top surface of the susceptor to be in contact with an underside of the substrate.

12. The apparatus according to claim 11, wherein the top surface of the detection electrode is leveled with the top surface of the susceptor, wherein the detection electrode is insulated from the susceptor.

13. The apparatus according to claim 12, wherein the susceptor is composed of a top plate and a heating block on which the top plate is placed, wherein both the detection electrode and its connecting wire leading to an outside of the reaction chamber are detachably embedded in the top plate via an insulating material and do not extend through the heating block.

14. The apparatus according to claim 12, wherein the susceptor is composed of a top plate and a heating block on which the top plate is placed, wherein the detection electrode is detachably embedded in the top plate via an insulating material, and a connecting wire connecting the detection electrode and an outside of the reaction chamber extends through the heating block via an insulating material.

15. The apparatus according to claim 12, wherein the susceptor includes a heater, wherein the detection electrode and its connecting wire leading to an outside of the reaction chamber are detachably embedded in the susceptor via an insulating material.

16. The apparatus according to claim 11, wherein the susceptor has trough-holes in which lift pins for lifting the substrate are inserted, said lift pins being movable with respect to the susceptor in an axial direction of the susceptor and insulated from the susceptor, wherein one of the lift pins serves as the detection electrode.

17. The apparatus according to claim 8, wherein the susceptor is grounded.
